(19) United States
(12) Patent Application Publication
(10) Pub. No.: US 2010/0177454 A1
(43) Pub. Date: Jul. 15, 2010

(54) Electrostatic chuck with dielectric inserts

(75) Inventors: Brent Elliot, Cupertino, CA (US); Frank Balma, Monte Sereno, CA (US); Dennis George Rex, Sunnyvale, CA (US); Alexander Veytser, Mountain View, CA (US)

Correspondence Address: CARR & FERRELL LLP, 2200 GENG ROAD, PALO ALTO, CA, 94303, US

(73) Assignee: Component Re-Engineering Company, Inc.

(21) Appl. No.: 12/319,633

(22) Filed: Jan. 9, 2009

(51) Int. Cl. H01L 21/683; H01B 19/00

(52) U.S. Cl. 361/234; 29/887

(57) ABSTRACT

An electrostatic chuck with dielectric inserts provides conveyance of cooling gas while eliminating arc path to a workpiece surface. The electrostatic chuck includes the workpiece surface configured to support a substrate such as a semiconductor wafer, a plenum configured to carry a cooling gas, and a plurality of dielectric inserts configured to provide communication of the cooling gas between the plenum and the workpiece surface. The dielectric inserts may comprise a passage to provide the communication of the cooling gas. The dielectric inserts may be further configured to prevent line-of-sight between the workpiece surface of the electrostatic chuck and a conducting surface within the electrostatic chuck.

### BACKGROUND

1. Field of the Invention

The present invention is generally related to electrostatic chucks. More specifically, the present invention is related to electrostatic chucks with dielectric inserts that provide conveyance of cooling gas and elimination of arc path.

2. Related Art

There are many techniques for processing substrates, such as semiconductor wafers, that involve electrostatic chucks for holding a substrate in place. These techniques may include use of plasmas, such as in semiconductor device fabrication, metal coating, and materials science research. These techniques may be used for depositing layers of material on, removing material from, or modifying a surface of the substrates.

For example, plasma enhanced chemical vapor deposition (PECVD) is widely used to deposit thin films from a vapor state to a solid state on a given substrate. In plasma ashing, a material, such as photoresist, may be removed from the substrate. Ion implantation may be used to change physical properties of the surface of the substrate.

In these techniques, the plasma is generally created by alternating current (AC) (e.g., radio frequency) or direct current (DC) discharge in a space containing reacting gases, the space being adjacent to the substrate. The substrate may be held in place by a device known as a chuck. Two general classes of chucks exist: mechanical chucks and electrostatic chucks. Mechanical chucks operate by clamping the periphery of the substrate. Electrostatic chucks, on the other hand, have gained popularity in that they overcome non-uniform coupling associated with mechanical chucks by evenly securing the entire area of the substrate. Additionally, electrostatic chucks do not obscure areas of the substrate that may be used for product.

Electrostatic chucks utilize a clamping force (e.g., coulombic or Johnson-Rahbeck) between oppositely charged surfaces to secure the substrate. A surface of the electrostatic chuck that contacts the substrate, which may be referred to as a workpiece surface, may be coated with an insulating material, such as a dielectric layer, to prevent short-circuiting between the oppositely charged surfaces. The clamping force is related to a voltage bias, a relative permittivity of intervening dielectric media (e.g., the dielectric layer of the workpiece surface as well as any interstitial gas), and a distance between the substrate and the workpiece surface.

To sink heat energy generated by the plasma from the substrate, sufficient thermal coupling between the substrate and the electrostatic chuck may be established. Since the processing techniques involving plasmas are practiced in a vacuous environment, a cooling gas, such as helium, is often introduced between the substrate and the electrostatic chuck to provide thermal coupling therebetween.

The cooling gas may be introduced between the electrostatic chuck and the substrate via channels or passages between the workpiece surface of the electrostatic chuck and a plenum or manifold carrying the cooling gas within the electrostatic chuck. The channels are customarily produced by drilling holes from the workpiece surface to the plenum. Since the portion of the electrostatic chuck that forms the workpiece surface is fabricated from a metal, such as aluminum, drilling the holes to produce the channels invariably exposes bare metal on side walls of the channels.

Catastrophic failure mechanisms can arise due to exposed conducting surfaces of the electrostatic chuck, such as exposed bare metal on the side walls of the channels and within the plenum, that have a direct path, or ‘line-of-sight’ to the substrate. Since the substrate and the exposed conducting surfaces are oppositely charged, line-of-sight provides an arc path from which DC arcing and ignition of the cooling gas can occur. These failure mechanisms can destroy the substrate and critically damage the electrostatic chuck and other equipment.

In a costly attempt to overcome the failure mechanisms associated with the exposed conducting surfaces, the channels may be laser machined to have a diameter of approximately 0.006 inches. This diameter is below a minimum threshold length for ionization of the cooling gas. As such, ionization of the cooling gas may not occur within the channels. Nevertheless, arcing may still occur above the channels at the workpiece surface if the side walls of the channels have a line-of-sight to the substrate. Thus, the prospect of catastrophic failure remains.

### SUMMARY OF THE CLAIMED INVENTION

Embodiments of the present invention alleviate or overcome prior problems associated with electrostatic chuck failure mechanisms.

In one claimed embodiment, an electrostatic chuck includes a workpiece surface configured to support a substrate, such as a semiconductor wafer. The electrostatic chuck may further include a plenum within the electrostatic chuck configured to carry a cooling gas. The electrostatic chuck also includes a number of dielectric inserts configured to provide communication of the cooling gas between the plenum and the workpiece surface. Each of the dielectric inserts may include a passage to provide the communication of the cooling gas.

In a further claimed embodiment of the present invention, dielectric inserts are provided that are configured to prevent line-of-sight between the workpiece surface and a conducting surface within an electrostatic chuck. The dielectric inserts may be further configured to electrically isolate the workpiece surface of the electrostatic chuck from the plenum. Furthermore, according to exemplary embodiments, dielectric inserts may comprise one or more of a ceramic material and glassy material in various embodiments.

In a third claimed embodiment of the present invention, methods for fabricating electrostatic chucks including dielectric inserts are disclosed. Such methods may include applying a dielectric layer to a workpiece surface of an electrostatic chuck, maintaining openings in the dielectric layer, and inserting dielectric inserts into the openings. When inserted, such dielectric inserts can prevent line-of-sight between a conducting surface and a workpiece surface of the electrostatic chuck (i.e., where a substrate may be located).

### BRIEF DESCRIPTION OF THE DRAWINGS

FIG. 1 is a diagram illustrating an exemplary system for processing substrates.

FIG. 2 illustrates a top plan view of an exemplary electrostatic chuck.

FIG. 3 illustrates a sectional view, corresponding to the top plan view presented in FIG. 2, of the exemplary electrostatic chuck.

FIG. 4 illustrates a detailed sectional view of a dielectric insert installed in the exemplary electrostatic chuck.

FIG. 5 is a flowchart of an exemplary method for providing the electrostatic chuck.

### DETAILED DESCRIPTION

Embodiments of the present invention provide electrostatic chucks with dielectric inserts that provide conveyance of cooling gas and elimination of arc path. Since the arc path may be eliminated, channels or passages that carry the cooling gas from the plenum to the workpiece surface of the electrostatic chuck may have increased diameters relative to those produced by laser machining. As such, the passages may have diameters greater than the minimum threshold length for ionization of the cooling gas. Therefore, the passages may be fabricable by means less costly than laser machining, such as high-speed grinding and drilling methods using diamond tooling. Additionally, since the diameters of the passages may be increased, fewer total passages may be required to sustain sufficient thermal coupling, thereby further reducing fabrication cost.

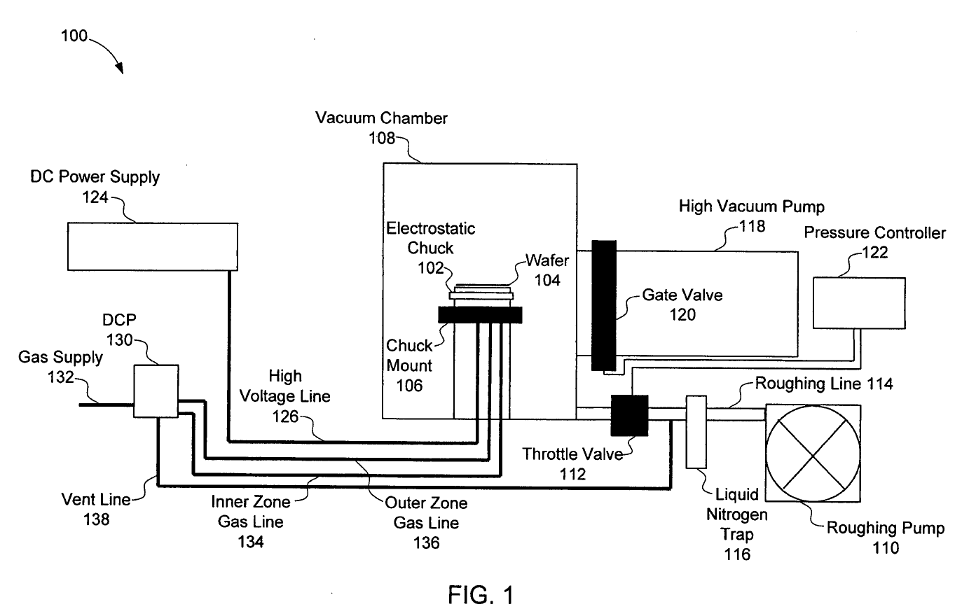

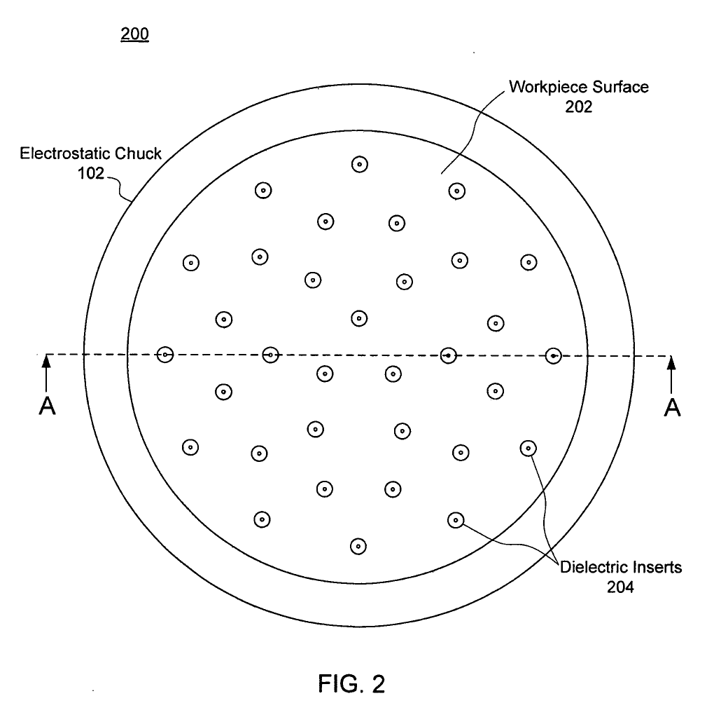

FIG. 1 is a diagram illustrating an exemplary system 100 for processing substrates. The system 100 of FIG. 1 includes an electrostatic chuck 102, a wafer 104 (e.g., a semiconductor wafer), and a chuck mount 106 housed by a vacuum chamber 108. The electrostatic chuck 102, or elements thereof, may be configured to support and secure various substrates such as the wafer 104. The electrostatic chuck 102 may be mounted to the chuck mount 106. The chuck mount 106 of FIG. 1 is configured to couple one or more of various electrical, gas, or fluid lines from outside of the vacuum chamber 108 to the electrostatic chuck 102. Details of the electrostatic chuck 102 are described further in connection with FIGS. 2, 3, and 4. Those skilled in the art will appreciate that the system 100 may include further components such as apparatus for generating plasma and introducing reacting gases or other processing materials to the vacuum chamber 108.

As depicted in FIG. 1, a vacuous environment within the vacuum chamber 108 is provided, in part, by a roughing pump 110 coupled to the vacuum chamber 108 by a roughing line 114. The roughing pump 110 may comprise a positive displacement pump such as a rotary vane pump, diaphragm pump, piston pump, roots blower, or various combinations thereof. A throttle valve 112 and a liquid nitrogen trap 116 may be installed in the roughing line 114 between the roughing pump 110 and the vacuum chamber 108 of FIG. 1.

The vacuous environment within the vacuum chamber 108 may be further provided by a high vacuum pump 118 such as a turbomolecular pump, diffusion pump, cryopump, ion pump, sorption pump, or various combinations thereof. As depicted in FIG. 1, the high vacuum pump 118 is separated from the vacuum chamber 108 by a gate valve 120. A pressure controller 122 electrically coupled to the throttle valve 112 and the gate valve 120 may be invoked during various pump-down or processing procedures to control opening and closing of the throttle valve 112 and the gate valve 120.

As mentioned, the electrostatic chuck 102 secures the wafer 104, or other substrate, by a clamping force. The clamping force may be generated by applying a DC voltage bias between the electrostatic chuck 102 and the wafer 104. The DC voltage bias may be provided by electrically coupling a DC power supply 124 to the electrostatic chuck 102 by a high voltage line 126. In one embodiment of the present invention, the DC voltage bias between the electrostatic chuck 102 and the wafer 104 may be 1000V.

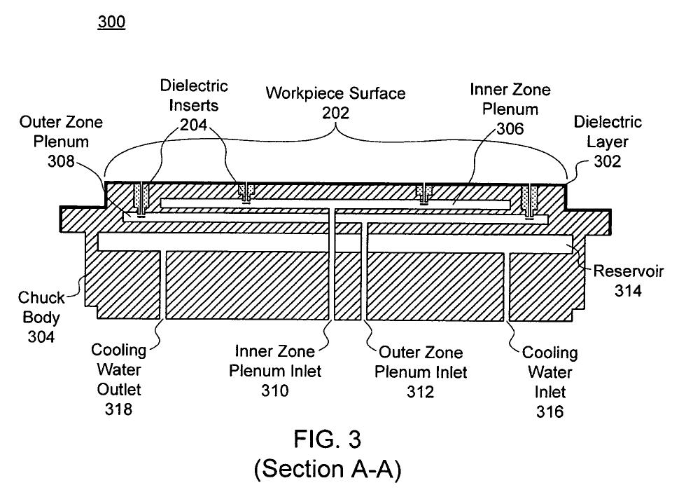

A digital pressure controller 130 (also known as a dual-zone pressure controller (DPC)) may control introduction of cooling gas to the chuck mount 104 and, consequently, the electrostatic chuck 102. The cooling gas from a gas source 132 may be metered to gas lines such as an inner zone gas line 134 and an outer zone gas line 136. The inner zone gas line 134 and the outer zone gas line 136 are discussed further in connection with FIG. 3. Additionally, excess cooling gas may be vented from the digital pressure controller 130 to the roughing line 114 via a vent line 138.

Referring now to FIG. 2, a top plan view 200 of the exemplary electrostatic chuck 102 is presented according to various embodiments. The top plan view 200 shows a workpiece surface 202 of the electrostatic chuck 102. The workpiece surface 202 is configured to support and secure various substrates, such as the wafer 104. As further illustrated in FIG. 3, the workpiece surface 202 may be coated with a dielectric material such as alumina to prevent short-circuiting between the electrostatic chuck 102 and the wafer 104 while oppositely charged.

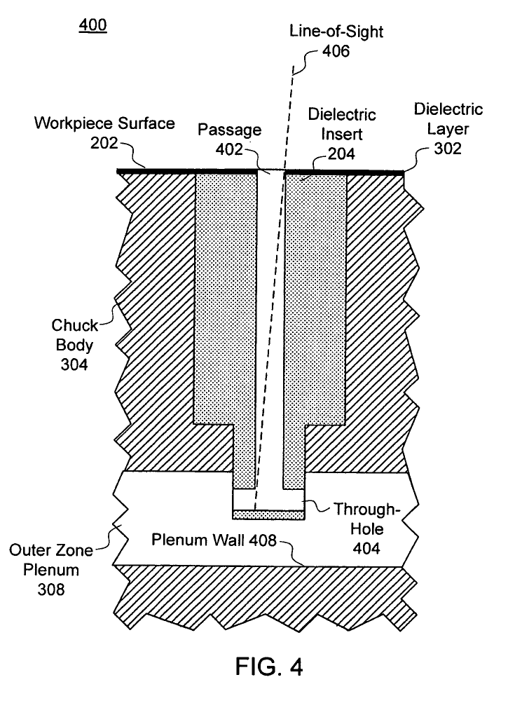

The top plan view 200 also shows a number of dielectric inserts 204. The dielectric inserts 204 convey the cooling gas to the workpiece surface 202. To prevent failure mechanisms such as arcing, the dielectric inserts 204 prevent line-of-sight between the workpiece surface 202, or the substrate supported thereon, and any conducting surface within the electrostatic chuck 102. Additional details of the dielectric inserts 204 concerning the conveyance of the cooling gas and the elimination of arc paths are discussed in connection with FIGS. 3 and 4.

The dielectric inserts 204 may be formed partly or wholly by various dielectric materials. The dielectric material may comprise one or more of a ceramic material or a glassy material. Ceramic materials include non-conducting materials with crystalline or partly crystalline microstructures such as oxides (e.g., alumina, titania, and zirconia), non-oxides (e.g., carbides, borides, nitrides, and silicides), and composites (e.g., particulate reinforced combinations of oxides and non-oxides). Glassy materials, on the other hand, include non-conducting materials with non-crystalline or amorphous microstructures such as soda-lime glass, borosilicate glass, and aluminum oxynitride.

There may be any number of dielectric inserts 204 included in the electrostatic chuck 102. The quantity of dielectric inserts 204 can be adjusted based on various concerns, such as gas flow and fabrication cost. Furthermore, the dielectric inserts 204 may be arranged in any regular or irregular fashion on the workpiece surface 202. In some embodiments, the dielectric inserts 204 are divided into groups, or ‘zones,’ having different cooling gas conveyance characteristics as illustrated in FIG. 3.

The workpiece surface 202 may further include one or more recessed areas (not shown). Such recessed areas may facilitate circulation of the cooling gas between the wafer 104 and the workpiece surface 202. In addition, exposed faces of the dielectric inserts 204 may be flush with, or extend beyond, the recessed areas.

The workpiece surface 202 may, in some embodiments, include protruding portions (not shown) that are configured to contact the wafer. These protruding portions may provide a seal between the periphery of the substrate (e.g., the wafer 104) and the workpiece surface 202. The seal may contain the cooling gas between the substrate and the workpiece surface 202. Additional protruding portions may be distributed across the workpiece surface 202 in order to support the substrate. In one embodiment of the present invention, the protruding portions may extend less than 0.001 inches and have polished topmost surfaces that contact the substrate.

FIG. 3 illustrates a sectional view 300 of the electrostatic chuck 102 and corresponds to section A-A of the top plan view 200. As in the top plan view 200, the workpiece surface 202 and the dielectric inserts 204 are visible in the sectional view 300. In the sectional view 300, however, a dielectric layer 302 is seen atop the workpiece surface 202. The dielectric layer 302 may include various dielectric materials such as alumina. Moreover, the dielectric layer 302 may be applied to the workpiece surface 202 by techniques known in the art. In some embodiments, the dielectric layer 302 may extend outward, beyond the workpiece surface 202, as depicted in FIG. 3, to cover all surfaces of the electrostatic chuck 102 that may potentially have line-of-sight to the substrate.

The sectional view 300 further illustrates that the electrostatic chuck 102 of FIG. 1 includes one or more plena within a chuck body 304 to contain or carry the cooling gas at a pressure greater than that of the vacuous environment within the vacuum chamber 108. As depicted in FIG. 3, the electrostatic chuck 102 includes an inner zone plenum 306 and an outer zone plenum 308. The inner zone plenum 306 may be coupled to the inner zone gas line 134 via an inner zone plenum inlet 310. Accordingly, the outer zone plenum 308 may be coupled to the outer zone gas line 136 via an outer zone gas inlet 312. In some embodiments, the plena (e.g., the inner zone plenum 306 and the outer zone plenum 308) may be annular while in other embodiments, the plena may be disc-shaped.

As discussed in further detail in connection with FIG. 4, the dielectric inserts 204 provide communication of the cooling gas between the one or more plena (e.g., the inner zone plenum 306 and the outer zone plenum 308) and the workpiece surface 202. The inner zone plenum 306 and the outer zone plenum 308 may contain the cooling gas at different pressures thereby providing differing cooling gas conveyance characteristics to the dielectric inserts 204 at various positions on the workpiece surface 202.

In some embodiments, the chuck body 304 is cooled. Cooling may occur through introduction of circulated water. In such an embodiment, the chuck body 304 may further include a reservoir 314, as well as a cooling water inlet 316 and a cooling water outlet 318. The cooling water inlet 316, in such an embodiment, is configured to introduce the cooling water to the reservoir 314 while the cooling water outlet 318 is configured to expel spent cooling water from the reservoir 314. Cooling of the chuck body 304 via circulated water may be performed either as an open cycle, where fresh water is continuously introduced and spent water is discarded, or as a closed cycle, where spent water is cooled and re-circulated. The system 100 may further comprise a water cooling unit (not shown) in embodiments having closed cycle circulated water cooling.

FIG. 4 illustrates a detailed sectional view 400 of the dielectric insert 204 installed in the electrostatic chuck 102 of FIG. 1. The detailed sectional view 400 depicts a physical relationship between the dielectric insert 204, the dielectric layer 302, the chuck body 304, and the outer zone plenum 308. As shown, the dielectric insert 204 includes an outer geometry configured to fit within an aperture or opening in the electrostatic chuck 102 at the workpiece surface 202. The dielectric insert 204 may be secured in the opening by press-fitting or other methods known in the art. Although the detailed sectional view 400 illustrates the physical relationship between the dielectric insert 204 and the outer zone plenum 308, the principles discuss herein are applicable to physical relationships between the dielectric insert 204 and other plena including the inner zone plenum 306.

The detailed sectional view 400 also illustrates a passage 402 and a through-hole 404 of the dielectric insert 204. The passage 402 provides communication of the cooling gas between the outer zone plenum 308 and the workpiece surface 202. In some embodiments, the passage 402 is in communication with the through-hole 404 as depicted in FIG. 4. The cooling gas may flow from the outer zone plenum 308, through the through-hole 404 and the passage 402, to the workpiece surface 202. In these cases, conveyance of the cooling gas to the workpiece surface 202, and any substrate supported thereon, is facilitated. The cooling gas, as described herein, may provide thermal coupling between the electrostatic chuck 102 and the substrate (e.g., the wafer 104) supported by the workpiece surface 202.

The dielectric insert 204 and the dielectric layer 302 may be configured to electrically isolate the workpiece surface 202 of the electrostatic chuck 102 from conducting surfaces within the electrostatic chuck 102. The dielectric layer 302 may extend over the topmost face of the dielectric insert 204 with a perforation that aligns with the passage 402 of the dielectric insert 204 as depicted in FIG. 3. In alternative embodiments, the topmost face of the dielectric insert 204 may be exposed such that the dielectric later 302 stops at the periphery of the dielectric insert 204.

Together, the passage 402 and the through-hole 404 insure that a line-of-sight 406 from workpiece surface 202 does not reach any conducting surface within the electrostatic chuck 102 such as a plenum wall 408. Any arc path from the electrostatic chuck 102 to any substrate supported by the workpiece surface 202 is eliminated. Additionally, since walls of the passage 402 and the though-hole 404 comprise a non-conducting medium such as a dielectric, arcing may not occur directly from the passage 402 or the through-hole 404 to the substrate.

In the embodiment shown in FIG. 4, the through-hole 404 is perpendicular to the passage 402. The though-hole 404 may, in alternative embodiments, be oblique to the passage 402 (not shown). Additionally, the through-hole 404 may be omitted, and replaced by a hole (not shown) that connects one side of the dielectric insert 204 to the passage 402. Further embodiments may include one or more passages such as the passage 402 or through-holes such as the through-hole 404. In another embodiment, the dielectric insert 204 includes a non-linear passage (not shown) to prevent the line-of-site 406 from reaching any conducting surface within the electrostatic chuck 102 such as the plenum wall 408. In yet another embodiment, the passage 402 passes directly and linearly from the workpiece surface 202 to the outer zone plenum 308 (not shown). In such an embodiment, the plenum wall 408 may be coated or otherwise concealed by a dielectric material (not shown) similar to that of the dielectric layer 302.

The passage 402 may not necessarily have a cross-sectional dimension (e.g., a diameter or a width) that is shorter than the minimum length required for ionization of the cooling gas. The minimum length required for ionization of the cooling gas may be defined by specific conditions within the passage 402 (e.g., pressure, type of cooling gas, etc.). In an embodiment of the present invention, the passage 402 includes a cross-sectional dimension that is greater than 0.01 inches. If ionization of the cooling gas does occur in the passage 402, arcing through the ionized cooling gas may still be prevented. For example, since the line-of-sight 406 does not connect any conducting surface within the electrostatic chuck 102 to the workpiece surface 202, arcing to the substrate having an opposite charge relative to the electrostatic chuck 102 is prevented.

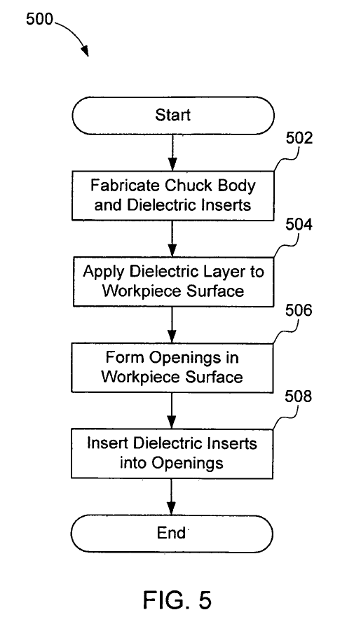

FIG. 5 illustrates an exemplary method 500 for producing the electrostatic chuck 102. Steps of this method may be performed in varying orders. Various steps may be added or subtracted from the method 500 and still fall within the scope of the present invention.

In step 502, the chuck body 304 and the dielectric inserts 204 are fabricated. The chuck body 304 may be formed of a metal such as aluminum and be fabricated by one or more of traditional machining and molding techniques. The dielectric inserts 204 may be fabricated by sintering, drilling, grinding, or various combinations thereof.

In step 504, a dielectric coating (e.g., the dielectric layer 302) is applied to the workpiece surface of the electrostatic chuck 102. The dielectric coating may be applied to the workpiece surface by various deposition techniques including chemical vapor deposition.

In step 506, openings are formed in the workpiece surface 202. The opening may be formed by drilling or milling. Dimensions of the opening may compatible with the external geometry of the dielectric inserts 204. Additionally, the opening may connect one or more plena (e.g., the inner zone plenum 306 and the outer zone plenum 308) to the workpiece surface 202.

In step 508, the dielectric inserts 204 are inserted into the openings in the workpiece surface 202. In some embodiments, the dielectric inserts 204 are press-fit into the openings. The dielectric inserts 204 may be configured to provide communication of the cooling gas between a plenum (e.g., the inner zone plenum 306 and the outer zone plenum 308) and the workpiece surface 202 of the electrostatic chuck 102. The dielectric inserts may be further configured to prevent line-of-sight between the workpiece surface 202 and a conducting surface within the electrostatic chuck 102.

The present invention has been described above with reference to exemplary embodiments. It will be apparent to those skilled in the art that various modifications may be made and other embodiments can be used without departing from the broader scope of the invention. Therefore, these and other variations upon the exemplary embodiments are intended to be covered by the present invention.

What is claimed is:

1. An electrostatic chuck, comprising:
a workpiece surface configured to support a wafer;
a plenum configured to carry a cooling gas; and
a plurality of dielectric inserts configured to provide communication of the cooling gas between the plenum and the workpiece surface, and to prevent line-of-sight between the workpiece surface and a conducting surface within the electrostatic chuck.

2. The electrostatic chuck of claim 1, wherein a passage within one or more of the plurality of dielectric inserts provides the communication of the cooling gas.

3. The electrostatic chuck of claim 2, wherein the passage is nonlinear.

4. The electrostatic chuck of claim 2, wherein a cross-sectional dimension of the passage exceeds a minimum length for ionization of the cooling gas.

5. The electrostatic chuck of claim 2, wherein a cross-sectional dimension of the passage is greater than one hundredth of an inch.

6. The electrostatic chuck of claim 1, wherein the workpiece surface of the electrostatic chuck includes a recessed area.

7. The electrostatic chuck of claim 6, wherein a face of each of the plurality of dielectric inserts is flush with the recessed area.

8. The electrostatic chuck of claim 1, wherein the workpiece surface includes a dielectric coating.

9. The electrostatic chuck of claim 1, wherein the workpiece surface includes a plurality of perforations aligned with elements of the plurality of dielectric inserts.

10. The electrostatic chuck of claim 1, wherein the workpiece surface includes one or more protruding portions.

11. The electrostatic chuck of claim 10, wherein the one or more protruding portions are configured to contact the wafer.

12. A dielectric insert for an electrostatic chuck, comprising:
a passage configured to provide communication of a cooling gas between a plenum and a workpiece surface of the electrostatic chuck, and to prevent line-of-sight between the workpiece surface and a conducting surface within the electrostatic chuck, wherein the dielectric insert may be configured to electrically isolate the workpiece surface of the electrostatic chuck from the plenum.

13. The dielectric insert of claim 12, wherein the dielectric insert is manufactured from a ceramic material.

14. The dielectric insert of claim 12, wherein the dielectric insert is manufactured from a glassy material.

15. The dielectric insert of claim 12, further comprising a through-hole in communication with the passage, wherein the through-hole is perpendicular to the passage.

16. The dielectric insert of claim 12, further comprising a through-hole in communication with the passage, wherein the through-hole is oblique to the passage.

17. The dielectric insert of claim 12, wherein the passage does not follow a straight line between the workpiece surface and the plenum.

18. The dielectric insert of claim 12, wherein a cross-sectional dimension of the passage exceeds a minimum length for ionization of the cooling gas.

19. The dielectric insert of claim 12, wherein a cross-sectional dimension of the passage is greater than one hundredth of an inch.

20. The dielectric insert of claim 12, further comprising an outer geometry configured to fit within an opening of the electrostatic chuck.

21. A method for fabricating an electrostatic chuck, the method comprising:
applying a dielectric layer to form a workpiece surface of an electrostatic chuck;
forming an opening through the applied dielectric layer of the workpiece surface to a plenum; and
inserting a dielectric insert into the opening, the dielectric insert being configured to provide communication of a cooling gas between the plenum and the workpiece surface, and to prevent line-of-sight between the workpiece surface and a conducting surface within the electrostatic chuck.

22. The method of claim 21, further comprising fabricating the dielectric insert using a ceramic material.

23. The method of claim 21, further comprising fabricating the dielectric insert using a glassy material.

24. The method of claim 21, further comprising fabricating the dielectric insert to include a through-hole in communication with a passage to the workpiece surface, wherein the through-hole is perpendicular to the passage and provides communication to the plenum.

25. The method of claim 21, further comprising fabricating the dielectric insert to include a through-hole in communication with a passage to the workpiece surface, wherein the through-hole is oblique to the passage and provides communication to the plenum.

26. The method of claim 21, further comprising fabricating the dielectric insert to include a passage between the workpiece surface and the plenum, wherein the passage does not follow a straight line.
